(19) United States
(12) Patent Application Publication
(10) Pub. No.: US 2026/0342114 A1
(43) Pub. Date: Oct. 29, 2026

(54) STAND FOR CHARGING ELECTRONIC DEVICE

(71) Applicant: Shenzhen Deone Innovation Technology Co., Ltd, Shenzhen (CN)

(72) Inventors: BEIJING HE, Xi'an (CN); JUN XU, Dongguan (CN); LEI YU, Shenzhen (CN)

(21) Appl. No.: 19/705,707

(22) Filed: Jun. 11, 2026

(30) Foreign Application Priority Data
Jul. 24, 2025 (CN) 202521551939.7

(51) Int. Cl. H02J 7/70; H05K 5/02

(52) U.S. Cl. CPC H02J 7/731; H05K 5/0213

(57) ABSTRACT

Provided is a stand for charging an electronic device. The stand is used for holding an electronic device. A first socket is arranged at the bottom of the electronic device. The stand includes a main body. The main body is provided with an accommodating slot configured to receive an electronic device. The main body includes a wiring duct. A bottom wall of the accommodating slot extends to the exterior via the wiring duct for a connecting wire to traverse and connect to the first socket. An insertion direction of the electronic device into the accommodating slot is a first direction. The wiring duct extends in a direction opposite to the first direction to extend through a side surface, in the direction opposite to the first direction, of the main body, such that the electronic device may be first connected to the connecting wire and then inserted into the accommodating slot.

### CROSS-REFERENCE TO RELATED APPLICATIONS

This application claims priority to Chinese Patent Application No. 202521551939.7, filed on Jul. 24, 2025, which is hereby incorporated by reference in its entirety.

### TECHNICAL FIELD

The present disclosure relates to the technical field of stands, in particular to a stand for charging an electronic device.

### BACKGROUND

During long-term use of an electronic device, users have to hold the electronic device by hand for a long time, leading to poor usage experience. In view of this, users often place the electronic device on a stand to shorten the time of holding the electronic device by hand.

Due to long-term use of electronic devices, users often experience interruptions of usage caused by low battery power, which compromises the long-term usage experience of the users. Therefore, a wiring duct is arranged at the bottom of the stand, and the wiring duct is connected to an accommodating slot for accommodating the electronic device, such that the electronic device in the accommodating slot may be charged in use, thereby preventing interruptions of use of the electronic device caused by low battery power.

Before charging of the electronic device, a connecting wire needs to extend through the wiring duct of the stand to be connected to a first socket in the bottom of the electronic device. When the electronic device is placed, it is necessary to align the connecting wire with the first socket. Because the connection portion of the connecting wire is located on the bottom wall of the accommodating slot, the electronic device, when inserted into the accommodating slot, will obstruct the field of view for observing the connecting wire, making it difficult to align and connect the electronic device with the connecting wire.

### SUMMARY

In view of the defects and deficiencies in the prior art, an objective of the present disclosure is to provide a stand for charging an electronic device. A wiring duct extends in a direction opposite to a first direction to extend through a side surface, in the direction opposite to the first direction, of a main body, such that an electronic device may be first connected to a connecting wire and then inserted into an accommodating slot, and in the process of placing the electronic device in the accommodating slot, the connecting wire is inserted into the wiring duct in the first direction.

To fulfill the above objective, the present disclosure adopts the following technical solution: a stand for charging an electronic device is used for holding an electronic device. A first socket is arranged at the bottom of the electronic device. The stand includes a main body. The main body is provided with an accommodating slot, and the electronic device is placed in the accommodating slot. The main body is provided with a wiring duct, and a bottom wall of the accommodating slot communicates with the outside via the wiring duct, such that a connecting wire extends through the wiring duct to be connected to the first socket. The direction in which the electronic device is inserted into the accommodating slot is a first direction. The wiring duct extends in a direction opposite to the first direction, such that the wiring duct extends through a side surface, in the direction opposite to the first direction, of the main body.

By adopting the above technical solution, the present disclosure fulfills the following beneficial effects: the wiring duct extends in the direction opposite to the first direction to extend through the side surface, in the direction opposite to the first direction, of the main body, such that an electronic device may be first connected to a connecting wire and then inserted into the accommodating slot; and in the process of placing the electronic device in the accommodating slot, the connecting wire is inserted into the wiring duct in the first direction, that is, the connecting wire extends through the side surface, in the direction opposite to the first direction, of the main body to be inserted into the wiring duct.

### BRIEF DESCRIPTION OF DRAWINGS

To more clearly explain the technical solutions in the embodiments of the present disclosure or the prior art, drawings used for describing the embodiments of the present disclosure or the prior art are briefly introduced below. Obviously, the drawings described below merely illustrate some embodiments of the present disclosure, and those ordinarily skilled in the art may obtain other drawings on the basis of the following ones without creative labor.

FIG. 1 is a schematic structural diagram of a stand according to an embodiment of the present disclosure.

FIG. 2 is a schematic structural diagram of the stand, from another perspective, according to an embodiment of the present disclosure.

FIG. 3 is a sectional view along A-A′ in FIG. 1.

### REFERENCE SIGNS

100, stand; 10, main body; 11, first side surface; 12, second side surface; 13, circulation cavity; 131, reinforcing rib; 14, second heat-dissipation opening; 20, accommodating slot; 21, first heat-dissipation opening; 22, grating; 23, recess; 24, first support surface; 25, second support surface; 26, bottom wall; 30, wiring duct; X, first direction; Y, second direction; Z, third direction.

### DESCRIPTION OF EMBODIMENTS

The present disclosure is described in further detail below in conjunction with the accompanying drawings.

The specific embodiments are merely intended to illustrate the present disclosure rather than limiting the present disclosure. After reading the specification, those skilled in the art may make various modifications to these embodiments as needed, and any such modifications made within the scope of the claims of the present disclosure shall be protected by the patent law.

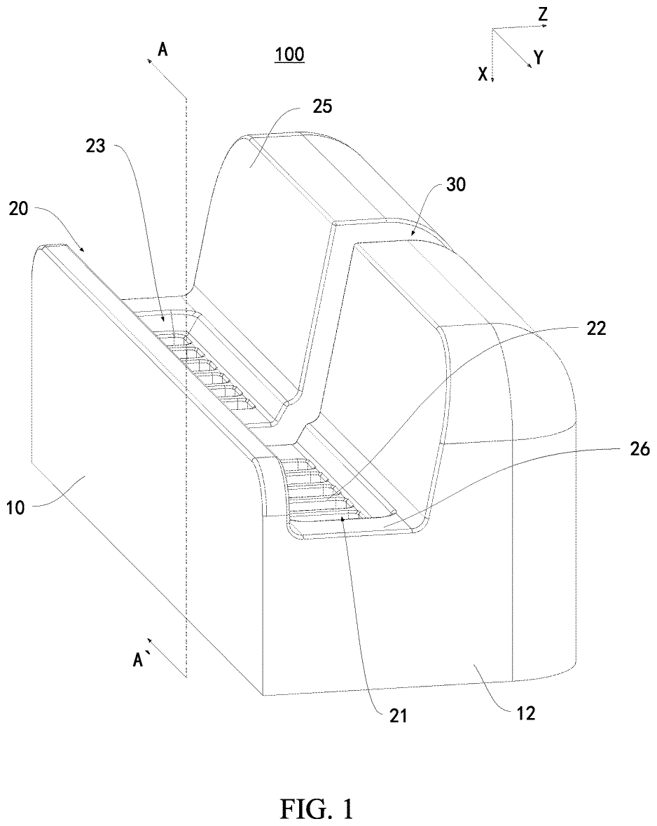

As shown in FIGS. 1-3, this embodiment relates to a stand 100 for charging an electronic device. The stand 100 is used for holding an electronic device. A first socket is arranged at the bottom of the electronic device, and the first socket is connected to an external connecting wire. The stand 100 includes a main body 10. The main body 10 is provided with an accommodating slot 20, and the electronic device is placed in the accommodating slot 20. The main body 10 is further provided with a wiring duct 30, and a bottom wall 26 of the accommodating slot 20 communicates with the outside via the wiring duct 30, such that the connecting wire from the outside extends through the wiring duct 30 to reach the accommodating slot 20 so as to be connected to the first socket, thereby facilitating charging or data transmission of the electronic device inserted into the accommodating slot 20. The direction in which the electronic device is inserted into the accommodating slot 20 is defined as a first direction X, and the wiring duct 30 at least partially extends in a direction opposite to the first direction X, such that the wiring duct 30 extends through a side surface, in the direction opposite to the first direction X, of the main body 10, and the electronic device may be first connected to the connecting wire and then inserted into the accommodating slot 20. In the process of inserting the electronic device into the accommodating slot 20, the connecting wire is inserted into the wiring duct 30 in the first direction X, that is, the connecting wire extends through the side surface, in the direction opposite to the first direction X, of the main body 10 to be inserted into the wiring duct 30. In this way, the problem that the electronic device, when inserted into the accommodating slot 20, obstructs the field of view for observing the connecting wire, which makes it difficult to align and connect the electronic device with the connecting wire is solved.

The wiring duct 30 at least partially extends in the first direction X, such that the depth of the wiring duct 30 is greater than that of the accommodating slot 20; and the wiring duct 30 is arranged in the middle of the accommodating slot 20 and divides the accommodating slot 20 into two uniform and symmetric portions. Because the first socket is generally arranged in the middle of the bottom of the electronic device, the wiring duct 30 is arranged in the middle to better fit the first socket of the electronic device, such that the electronic device may be supported in the accommodating slot 20 more stably after being placed in the accommodating slot 20.

As shown in FIGS. 1-3, the main body 10 includes a first side surface 11 and a second side surface 12 which are opposite to each other. The direction from the first side surface 11 to the second side surface 12 is defined as a second direction Y. A third direction Z is perpendicular to the first direction X and is also perpendicular to the second direction Y. The accommodating slot 20 extends in the second direction Y, and the wiring duct 30 extends in the third direction Z. Compared with an embodiment where the wiring duct 30 is formed in the bottom wall 26 of the accommodating slot 20, by designing the extension direction of the accommodating slot 20 to be perpendicular to the extension direction of the wiring duct 30, the connecting wire will not pass through the first side surface 11 or the second side surface 12, such that the overall space needed in the second direction Y during use is reduced.

Specifically, the first direction X is a height direction of the stand 100, the second direction Y is a length direction of the stand 100, and the third direction Z is a width direction of the stand 100.

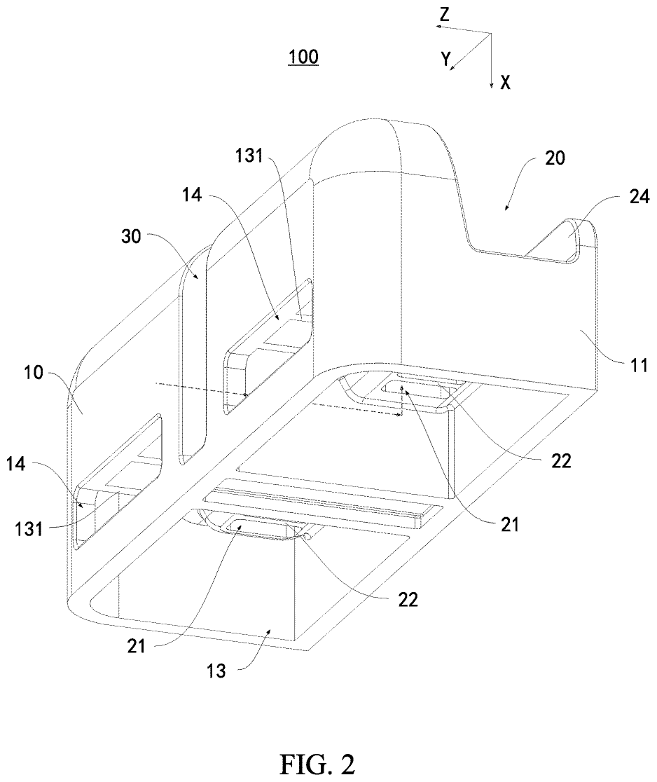

As shown in FIGS. 1 and 2, the accommodating slot 20 extends through the first side surface 11 and the second side surface 12, such that the size of the electronic device placed in the accommodating slot 20 in the second direction Y may be greater than that of the stand 100 in the second direction Y, and the stand 100 may adapt to an electronic device with a larger size in the second direction Y, thus improving the adaptability of the stand 100.

As shown in FIGS. 1-3, a first heat-dissipation opening 21 is formed in the bottom wall 26 of the accommodating slot 20. A heat-dissipation window is arranged at the bottom of the electronic device. When the electronic device is inserted into the accommodating slot 20, the first heat-dissipation opening 21 is aligned with the heat-dissipation window. A circulation cavity 13 is formed in the main body 10, and the first heat-dissipation opening 21 communicates with the circulation cavity 13. The main body 10 is further provided with a second heat-dissipation opening 14, and the circulation cavity 13 communicates with the outside via the second heat-dissipation opening 14, such that the cavity in the electronic device, the heat-dissipation window, the first heat-dissipation opening 21, the circulation cavity 13, the second heat-dissipation opening 14 and the outside sequentially communicate with each other.

In a case where the heat-dissipation window functions as an air inlet of the electronic device, an airflow flows through the second heat-dissipation opening 14, the circulation cavity 13 and the first heat-dissipation opening 21 to reach the heat-dissipation window, and the specific airflow path is indicated by the dotted line below. In this way, air enters the electronic device via an air passage formed by the main body 10, such that air intake and heat dissipation of the electronic device are guaranteed, and the situation where the heat-dissipation effect of the electronic device is affected due to blockage of the heat-dissipation window is avoided, thus guaranteeing the usage experience of users.

In a case where the heat-dissipation window functions as an air outlet of the electronic device, a hot airflow produced by the electronic device flows through the heat-dissipation window, the first heat-dissipation opening 21, the circulation cavity 13 and the second heat-dissipation opening 14 to be discharged to the outside. In this way, the hot airflow produced by the electronic device is discharged to the outside via the air passage, and air discharge and heat dissipation of the electronic device are guaranteed, thereby avoiding heat accumulation and guaranteeing the usage experience of users.

As shown in FIGS. 1-3, the second heat-dissipation opening 14 is located on a side, in the first direction X, of the first heat-dissipation opening 21, such that an outlet airflow from the first heat-dissipation opening 21 flows in the first direction X, and then flows towards the second heat-dissipation opening 14. Or, an inlet airflow from the second heat-dissipation opening 14 flows to enter the circulation cavity 13, and then flows in the direction opposite to the first direction X to reach the first heat-dissipation opening 21. In a scheme where the second heat-dissipation opening 14 is located on a side, in the direction opposite to the first direction X, of the first heat-dissipation opening 21, the direction of the airflow needs to be changed at least twice, which leads to a large air resistance, thus compromising the heat-dissipation effect of the electronic device. In this scheme, the direction of the airflow is changed twice as follows: the airflow flows in the first direction X, then flows in the second direction Y or the third direction Z, and then flows in the direction opposite to the first direction X. The arrangement of the second heat-dissipation opening 14 on the side, in the first direction X, of the first heat-dissipation opening 21 reduces the air resistance and guarantees airflow circulation, thereby guaranteeing the heat-dissipation effect of the electronic device.

In this embodiment, the second heat-dissipation opening 14 is formed in a side, in the third direction Z, of the main body 10 and located on the side, in the first direction X, of the first heat-dissipation opening 21, that is, the height at which the second heat-dissipation opening 14 is located is less than the height at which the first heat-dissipation opening 21 is located, such that the airflow enters the circulation cavity 13 from the second heat-dissipation opening 14 in the back side of the main body 10 and flows upward to the first heat-dissipation opening 21, or the airflow enters the circulation cavity 13 from the first heat-dissipation opening 21 in the bottom wall 26 of the accommodating slot 20 and flows towards the back side to reach the second heat-dissipation opening 14.

In some embodiments, the second heat-dissipation opening 14 is formed in the first side surface 11 or the second side surface 12 of the main body 10 or is formed in a side, in a direction opposite to the third direction Z, of the main body 10, and the second heat-dissipation opening 14 is located on the side, in the first direction X, of the first heat-dissipation opening 21, that is, the height at which the second heat-dissipation opening 14 is located is less than the height at which the first heat-dissipation opening 21 is located.

In some other embodiments, the second heat-dissipation opening 14 is located on the side, in the direction opposite to the first direction X, of the first heat-dissipation opening 21, that is, the height at which the second heat-dissipation opening 14 is located is greater than the height at which the first heat-dissipation opening 21 is located. To be specific, the position where the second heat-dissipation opening 14 is located is higher than the bottom wall 26 of the accommodating slot 20, that is, at least one side wall forming the accommodating slot 20 is hollowed out and communicates with the circulation cavity 13, and the second heat-dissipation opening 14 is formed in an outer side surface of the main body 10. Compared with the embodiment mentioned above, the air resistance in this embodiment is relatively large, which is not beneficial to airflow circulation and heat dissipation of the electronic device.

The heat-dissipation window generally extends in an extension direction of the bottom surface of the electronic device, such that the size of the heat-dissipation window may be increased to guarantee the heat-dissipation effect of the electronic device. To adapt to the heat-dissipation window, the first heat-dissipation opening 21 also extends in the second direction Y, which reduces the mechanical strength of the stand 100 (to be specific, the mechanical strength of the bottom wall 26 of the accommodating slot 20 is reduced), making the stand 100 prone to damage.

As shown in FIGS. 1-3, in this embodiment, the first heat-dissipation opening 21 is provided with a plurality of gratings 22 to guarantee the mechanical strength at the first heat-dissipation opening 21, such that the stand 100 is prevented from being damaged.

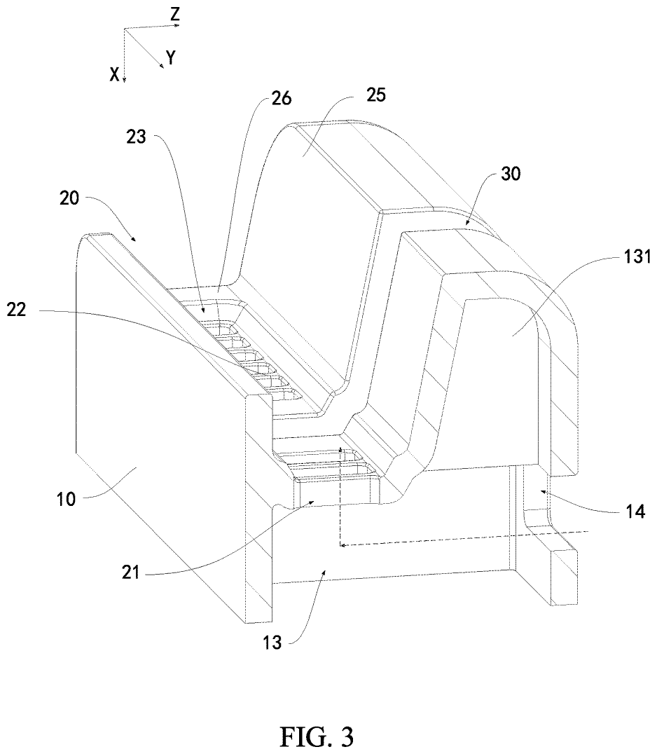

As shown in FIGS. 2-3, a plurality of reinforcing ribs 131 are arranged in the circulation cavity 13. The mechanical strength of the stand 100 is guaranteed by means of the reinforcing ribs 131, thus preventing the stand 100 from being damaged.

In some embodiments, the reinforcing ribs 131 are arranged on an air circulation portion in the circulation cavity 13, and the reinforcing ribs 131 at least partially extend from the first heat-dissipation opening 21 to the second heat-dissipation opening 14 to guarantee airflow circulation, such that the heat-dissipation effect of the electronic device will not be affected.

Because the electronic device is generally inserted into the accommodating slot 20 obliquely, only a portion of the heat-dissipation opening is aligned with the heat-dissipation window, which limits air circulation and compromises the heat-dissipation effect of the electronic device.

As shown in FIGS. 1 and 3, a recess 23 is formed in the bottom wall 26 of the accommodating slot 20, and the first heat-dissipation opening 21 is formed in a bottom surface of the recess 23. By means of the recess 23, the first heat-dissipation opening 21 is prevented from being closely attached to the bottom surface of the electronic device, the electronic device is spaced apart from the first heat-dissipation opening 21 by the height of the recess 23, and an airflow may pass through the recess 23 between the electronic device and the first heat-dissipation opening 21, such that airflow circulation is guaranteed, thereby guaranteeing the heat-dissipation effect of the electronic device.

In some embodiments, the first heat-dissipation opening 21 is provided with gratings 22 to guarantee the mechanical strength at the first heat-dissipation opening 21 of the stand 100. The heat-dissipation window of the electronic device is also provided with gratings 22 to guarantee the mechanical strength at the heat-dissipation window. When the electronic device is inserted into the accommodating slot 20, the gratings 22 of the first heat-dissipation opening 21 are staggered with the gratings 22 of the heat-dissipation window, for example, each of the gratings 22 of the first heat-dissipation opening 21 is aligned with a gap between two gratings 22 of the heat-dissipation window, so the air resistance is increased, which limits airflow circulation and compromises the heat-dissipation effect of the electronic device. Because the recess 23 is formed in the bottom wall 26 of the accommodating slot 20 and the first heat-dissipation opening 21 is formed in the bottom surface of the recess 23, the first heat-dissipation opening 21 is prevented from being closely attached to the bottom surface of the electronic device and is spaced apart from the electronic device by the height of the recess 23 to ensure that an airflow passes through the recess 23 between the electronic device and the first heat-dissipation opening 21, such that airflow circulation is guaranteed, thereby guaranteeing the heat-dissipation effect of the electronic device.

As shown in FIGS. 1 and 3, the recess 23 communicates with the wiring duct 30, such that an airflow may flow in or out of the recess 23 via the wiring duct 30, and the heat-dissipation window communicates with the outside via the recess 23 and the wiring duct 30 to form an air passage, thereby guaranteeing the heat-dissipation effect of the electronic device.

As shown in FIGS. 1 and 3, the accommodating slot 20 includes a first support surface 24, a second support surface 25 and a bottom wall 26. The bottom wall 26 connects the first support surface 24 and the second support surface 25. The second support surface 25 is used for supporting at least a portion of the back side of the electronic device, the bottom wall 26 is used for supporting at least a portion of the bottom surface of the electronic device, and the first support surface 24 is used for supporting at least a portion of the bottom surface or the front side of the electronic device. An included angle is formed between the second support surface 25 and the first direction X, such that the back side of the electronic device leans against the second support surface 25, that is, when the electronic device is inserted into the accommodating slot 20, an included angle is formed between the electronic device and the first direction X to ensure that a screen on the front side of the electronic device obliquely faces upward, such that users can use the screen of the electronic device.

In use of the stand 100, because the screen on the front side of the electronic device needs to remain exposed for viewing by users, the size, in the third direction Z, of the side wall of the accommodating slot 20 that forms the oblique second support surface 25 is greater than that of the other side wall of the accommodating slot 20. To reduce the weight of the stand 100, a cavity is formed inside this side wall, and the cavity may constitute a portion of the circulation cavity 13. Moreover, to guarantee the mechanical strength of the main body 10, reinforcing ribs 131 are arranged in this portion of the circulation cavity 13, that is, the reinforcing ribs 131 are arranged in the side wall forming the accommodating slot 20 to guarantee the mechanical strength of the side wall.

As shown in FIGS. 1 and 3, the accommodating slot 20 includes a first support surface 24, a second support surface 25 and a bottom wall 26. The bottom wall 26 connects the first support surface 24 and the second support surface 25. The second support surface 25 is used for supporting at least a portion of the back side of the electronic device, the bottom wall 26 is used for supporting at least a portion of the bottom surface of the electronic device, and the first support surface 24 is used for supporting at least a portion of the bottom surface or the front side of the electronic device. The size of the first support surface 24 in the first direction X is less than that of the second support surface 25 in the first direction X, such that a screen on the front side of the electronic device is exposed, and the electronic device is supported and limited by the first support surface 24.

The above embodiments are merely used for explaining the technical solution of the present disclosure rather than limiting the present disclosure. Other modifications or equivalent substitutions made to the technical solution of the present disclosure by those skilled in the art without departing from the spirit and scope of the technical solution of the present disclosure should also fall within the scope of the claims of the present disclosure.

What is claimed is:

1. A stand for charging an electronic device, used for holding an electronic device, a first socket being arranged at a bottom of the electronic device, the stand comprising a main body, the main body being provided with an accommodating slot, the electronic device being placed in the accommodating slot, the main body being provided with a wiring duct, a bottom wall of the accommodating slot communicating with an outside via the wiring duct to allow a connecting wire to extend through the wiring duct to be connected to the first socket, and a direction in which the electronic device is inserted into the accommodating slot being a first direction, wherein the wiring duct at least partially extends in a direction opposite to the first direction, such that the wiring duct extends through a side surface, in the direction opposite to the first direction, of the main body.

2. The stand according to claim 1, wherein the main body comprises a first side surface and a second side surface which are opposite to each other, a direction from the first side surface to the second side surface is a second direction, a third direction is perpendicular to the first direction and is also perpendicular to the second direction, the accommodating slot extends in the second direction, and the wiring duct extends in the third direction.

3. The stand according to claim 2, wherein the accommodating slot extends through the first side surface and the second side surface.

4. The stand according to claim 1, wherein a first heat-dissipation opening is formed in the bottom wall of the accommodating slot, a heat-dissipation window is arranged at the bottom of the electronic device, the first heat-dissipation opening is aligned with the heat-dissipation window, a circulation cavity is formed in the main body, the first heat-dissipation opening communicates with the circulation cavity, a second heat-dissipation opening is formed in the main body, and the circulation cavity communicates with the outside via the second heat-dissipation opening.

5. The stand according to claim 4, wherein the second heat-dissipation opening is located on a side, in the first direction, of the first heat-dissipation opening.

6. The stand according to claim 4, wherein the first heat-dissipation opening is provided with a plurality of gratings.

7. The stand according to claim 4, wherein a plurality of reinforcing ribs are arranged in the circulation cavity.

8. The stand according to claim 7, wherein the reinforcing ribs at least partially extend in a direction from the first heat-dissipation opening to the second heat-dissipation opening.

9. The stand according to claim 4, wherein a recess is formed in the bottom wall of the accommodating slot, and the first heat-dissipation opening is formed in a bottom surface of the recess.

10. The stand according to claim 9, wherein the recess communicates with the wiring duct.

11. The stand according to claim 1, wherein the accommodating slot comprises a first support surface, a second support surface and a bottom wall, the bottom wall connects the first support surface and the second support surface, the second support surface is used for supporting at least a portion of a back side of the electronic device, and an included angle is formed between the second support surface and the first direction.

12. The stand according to claim 1, wherein the wiring duct at least partially extends in the first direction, such that a depth of the wiring duct is greater than that of the accommodating slot.

13. The stand according to claim 12, wherein the wiring duct divides the accommodating slot into two uniform and symmetric portions.

14. The stand according to claim 11, wherein a size of the first support surface in the first direction is less than that of the second support surface in the first direction.

15. The stand according to claim 5, wherein the main body comprises a first side surface and a second side surface which are opposite to each other, a direction from the first side surface to the second side surface is a second direction, a third direction is perpendicular to the first direction and is also perpendicular to the second direction, and the second heat-dissipation opening is formed in a side, in the third direction, of the main body.

16. The stand according to claim 5, wherein the main body comprises a first side surface and a second side surface which are opposite to each other, a direction from the first side surface to the second side surface is a second direction, a third direction is perpendicular to the first direction and is also perpendicular to the second direction, and the second heat-dissipation opening is formed in the first side surface or the second side surface of the main body, or is formed in a side, in a direction opposite to the third direction, of the main body.

17. The stand according to claim 2, wherein the first direction is a height direction of the stand, the second direction is a length direction of the stand, and the third direction is a width direction of the stand.
